(19) United States
(12) Patent Application Publication
(10) Pub. No.: US 2017/0226652 A1
(43) Pub. Date: Aug. 10, 2017

(54) METHODS OF MANUFACTURING ELECTRODES BY IN-SITU ELECTRODEPOSITION AND DEVICES COMPRISING SAID ELECTRODES

(71) Applicant: Cambridge Display Technology, Ltd., Godmanchester (GB)

(72) Inventor: Jonathan Pillow, Godmanchester (GB)

(73) Assignee: Cambridge Display Technology, Ltd., Godmanchester (GB)

(21) Appl. No.: 15/422,733

(22) Filed: Feb. 2, 2017

(30) Foreign Application Priority Data
Feb. 5, 2016 (GB) 1602109.9

(51) Int. Cl. C25D 13/02; H01M 4/04; H01L 51/52; H01L 51/00; H01L 51/56; H01L 51/50

(52) U.S. Cl. CPC C25D 13/02; H01L 51/56; H01L 51/5012; H01L 51/5032; H01L 51/5253; H01L 51/5056; H01L 51/5092; H01L 51/0021; H01L 51/5206; H01L 51/5221; H01M 4/0457

(57) ABSTRACT

This invention relates to a method for fabrication of electrode material in electronic devices by in situ-electrodeposition of metal or metalloid ions that are present in the device. In another aspect, the present invention relates to electronic devices and charge storage devices comprising the electrodes manufactured by said method. Furthermore, the present invention further relates to a method of enhancing charge injection in an electronic device or charge storage device comprising the steps of: pre-assembling an electronic device or charge storage device and subsequently applying an electric field to effect electrodeposition of an electrode layer in situ by reducing the metal or metalloid ions to a non-ionic state.

### RELATED APPLICATIONS

This application claims the benefits under 35 U.S.C. §119(a)-(d) or 35 U.S.C. §365(b) of British application number 1602109.9, filed Feb. 5, 2016, the entirety of which is incorporated herein by reference.

### FIELD OF INVENTION

This invention relates to a method for fabrication of electrode material in electronic devices by in situ-electrodeposition of metal or metalloid ions that are present in the device. In another aspect, the present invention relates to electrodes manufactured by said method and electronic and charge storage devices comprising the electrodes.

### BACKGROUND OF THE INVENTION

A large number of charge storage devices (e.g. thin film batteries) and electronic devices (e.g. organic thin-film optoelectronic devices including organic light-emitting diodes (OLEDs), organic thin-film transistors (TFTs) or organic solar cells (OSCs)), require at least one electrode material which exhibits a work function that is sufficiently low to either inject electrons into or collect electrons from the lowest unoccupied orbital (LUMO) of an adjacent layer, which may be a semiconductor layer, for example, as there is often an energetic barrier resulting from a mismatch between the energy level of the semiconducting material (HOMO or LUMO; valence or conduction band) and the work function of the electrode material.

In terms of materials having a low work function, various metals, such as Li, Na, Mg, Ca or Zn, for example, represent suitable candidates for said electrodes. However, low-work function electrode layers are usually applied by using thermal evaporation or sputtering, which is expensive, complicated and not readily applicable to many metals, such as Zn. In addition, these electrodes must be handled in high vacuum and necessitate elaborate equipment due to the high reactivity of the pure metals towards air and water.

In the recent years, different strategies have been proposed to solve at least some of those problems. For example, Zhou et al., Science 2012, 336(2) 327-336 disclose that the work function of conductors may be reduced by modifying their surface with polyethyleneimines, which allows the use of alternative electrode materials that are less prone to oxidation. However, said method requires an additional manufacturing step, and it still remains difficult to achieve a work function as low as that of pure alkali metals, for example, by using this method.

An alternative approach is taken in US 2005/0019976 A1. Herein, electrodeposition and printing techniques which do not require vacuum environments are disclosed. Also, WO 2008/127111 A1 proposes a method of manufacturing an electrode by electrodeposition, wherein a plating liquid comprising an ionic liquid and metal or metalloid ions is applied, so that the latter are reduced and deposited to form an electrode on the surface of an electro-active substance.

However, these methods require a drying step and elaborate processing of the formed electrodes under inert gas atmosphere so as to avoid contact with air and water. Moreover, the possible device configurations obtainable by these methods are limited in terms of electrode placement, since due to the reactivity of the electrode material towards residual solvent (e.g. water), the deposition of solution-processed layers on top of the electrode material (or alternatively the deposition of the electrode on top of a solution-processed layer) is either not possible or results in a non-uniform and deteriorated electrode layer.

WO 2013/019993 A1 relates to a method of enhancing charge injection by providing an isopotential source layer comprising non-reducible mobile ions. However, a method of preparation of electrodes having low work function, let alone a method solving the abovementioned problems, is not disclosed.

Hence, it remains desirable to provide an inexpensive and simple method for the preparation of low work function electrodes, which may be used to manufacture a large variety of device configurations.

Furthermore, it would be desirable to provide electronic devices and charge storage devices, wherein electrodes are implemented so as to facilitate electron injection into a charge collection layer without having to cope with the challenges normally involved with the handling of low work function material.

### SUMMARY OF THE INVENTION

The present invention solves this object with the subject matter of the claims as defined herein. The advantages of the present invention will be further explained in detail in the section below and further advantages will become apparent to the skilled artisan upon consideration of the invention disclosure.

Generally speaking, the present invention describes a method of manufacturing electrodes in an electronic device or a charge storage device, comprising the steps of: providing a multilayer film comprising: a electrodeposition layer formed of a plating composition comprising metal or metalloid ions and a n-type electroactive material, and a negative charge collection layer in contact with the electrodeposition layer; and subsequently electrodepositing an electrode layer in situ on a surface of the negative charge collection layer by reducing the metal or metalloid ions to a non-ionic state. Thereby, it is possible to create a low work function electrode after the device structure has been at least partly pre-assembled, so that the multilayer film may be encapsulated against air and/or liquids prior to the electrodeposition step. Thus, the method solves the problem of providing low work function material such as Zn, Mg, Ca or Li in a device without requiring complex equipment needed to handle these pure materials due to their high reactivity towards air and water. Furthermore, the method significantly expands the number of possible device configurations. Method of enhancing charge injection in an electronic device or charge storage device comprising the steps of: pre-assembling an electronic device or charge storage device, wherein the pre-assembled device comprises a electrodeposition layer formed of a plating composition comprising metal or metalloid ions and an n-type electroactive material; and subsequently applying an electric field to the electronic device or charge storage device so as to effect electrodeposition of an electrode layer in situ by reducing the metal or metalloid ions to a non-ionic state.

Other aspects of the present invention are electronic devices and charge storage device manufactured by the abovementioned methods.

Preferred embodiments of electronic devices, charge storage devices as well as their method of manufacturing and other aspects of the present invention are described in the following description and the claims.

### BRIEF DESCRIPTION OF THE DRAWINGS

FIG. 1 illustrates the formation of the electrode layer by the in situ electrodeposition according to the present invention.

FIG. 2 schematically illustrates the reduction of the electron injection barrier by generating a low work function electrode in situ.

FIG. 3 schematically illustrates an exemplary top-emission organic light-emitting device.

### DETAILED DESCRIPTION OF THE INVENTION

### Methods of In Situ Electrode Electrodeposition and Charge Injection

For a more complete understanding of the present invention, reference is now made to the following description of the illustrative embodiments thereof:

This invention describes a process for making an electrode in situ inside the device using electrodeposition and devices produced by using this process.

In one embodiment, the present invention relates to a method of manufacturing an electronic device or a charge storage device, comprising the steps of: providing a multilayer film comprising a electrodeposition layer formed of a plating composition comprising metal or metalloid ions and an n-type electroactive material, and a negative charge collection layer in contact with the electrodeposition layer; and subsequently electrodepositing an electrode layer in situ on a surface of the negative charge collection layer by reducing the metal or metalloid ions to a non-ionic state.

The expression “in situ electrodeposition”, as used herein, refers to the generation of the electrode layer by applying an electric field to the multilayer film or the electronic/charge storage device, which has been previously at least partly preassembled so that it comprises the multilayer film. While not being limited thereto, the application of electric field may be achieved by running the fabricated device under operating conditions.

Accordingly, this is entirely opposed to conventional techniques, wherein electrodes are electrodeposited in a layer-by-layer process or wherein the electrode layer is laminated onto other layers or films after having been electrodeposited. Hence, the electrode preparation method generally does not require to be performed by highly skilled personnel and can be carried out in a relatively simple manner without the use of complex equipment. Moreover, since the material to form the electrode is present in ionic state until the pre-assembly has been completed, elaborate measures (e.g. vacuum techniques or use of inert gases) to prevent oxygen and/or water from deteriorating the reactive electrode material are not required or may be reduced to a minimum. Hence, the costs associated with the manufacture of the electrode and the device may be remarkably reduced. In addition, it becomes possible to deposit semiconducting material can on top of the location where the new electrode is to be formed, so that the device orientation can be reversed, for example.

Preferably, the electrodeposition layer is present in the multilayer film as an intermediate layer, i.e. as a layer interposed between the multiple layers of the multilayer film, as is illustrated in FIG. 1.

It is further preferred that the multilayer film comprises a positive charge collecting layer at the side of the electrodeposition layer opposed to the negative charge collecting layer. Depending on the purpose of the finished device, the multilayer structure may contain one (or more) additional layer(s), such as hole-injecting layers (HIL), electron-injecting layers (EIL), exciton-blocking layer (XBL), spacer layers, connecting layers, hole-blocking layers, and separator layers, for example.

In a further preferred embodiment of the present invention, the electrodeposition layer is a solution-processed layer. Namely, a further advantage of this invention is that the electrochemically deposited electrode is capable of acting as an internal getter, removing trace quantities of air and/or liquids (e.g. water and oxygen) from the device, since the metal(loid) material constituting the electrode layer is usually reactive towards air and/or liquids, thereby enabling by reaction their removal from the device and preventing them from causing more substantial problems, such as the so-called redox shuttle process in batteries that can cause charge leakage. Hence, it becomes possible to easily deposit an electrode in contact with a solution-processed layer, which often contains minor residues of trace water originating from the processing solvent.

In a preferred embodiment, the multilayer film and/or the electronic/charge storage device have been encapsulated against air and/or liquids prior to the electrodeposition step so as to ensure that the amount of air and/or liquids potentially contacting the electrode layer (e.g. at the side of a multilayer stack) is limited to the contents actually present in the device and to prevent external air and/or liquids from deteriorating the function of the electrode layer. This allows the device to be prepared in a much simpler manner, as a reactive electrode is not present until the other layers have been assembled and the device is encapsulated away from air, water or other materials that could degrade the electrode.

The provision of electrodeposition layer formed of a plating composition comprising metal or metalloid ions and an n-type electroactive material is not particularly limited and may be achieved by techniques customary in the art. By way of example, the electrodeposition layer may be deposited by inkjet printing, screen printing, blade coating, roller coating, nanoimprinting, table coating and spin coating, preferably by spin coating. It is to be noted that, contrary to the method of thermally evaporating electrodes, the electrodeposition layer may be provided under relatively mild conditions, i.e. low temperatures, which favourably allows the electrode to be provided on a temperature-sensitive substrate.

The electrodeposition layer is formed of a plating composition essentially comprising—beside of an n-type electroactive material—metal ions or metalloid ions, which are reduced during electrodeposition to a non-ionic state to form the electrode layer. Within the electrodeposition layer, the metal(loid) ions may be distributed randomly or in a predetermined pattern. Also, there may be a gradient in the metal(loid) ion concentration along the thickness of the electrodeposition layer.

The overall electrochemical reaction may be summarized by the following half-cell electrode potential reaction (I):

Mⁿ⁺+n e⁻→M_{(metal(loid))} (I)

This process is particularly applicable to deposit a negative electrode at a negative charge-collection material (where electrons are injected into a device), as the ions are attracted towards this side of the device under the influence of the electric field.

A schematic representation of this process is illustrated in FIG. 1. Under influence of the electric field, the metal ions or metalloid ions (Mⁿ⁺) migrate towards the negative charge-collection layer (1). Once they are close enough to the charge-collection layer for electron transfer to be efficient, the metal(loid) ions are reduced and so the metal(loid) is deposited in vicinity or in contact with the charge-collection material. Once formed, the electrode will stay as a permanent component of the device.

In a preferred embodiment of the invention, the deposited electrode is in full electrical contact with the charge-collection material.

The potential difference required for the electrode to be electrodeposited depends on the mobility of the cation through the n-type electroactive material film, the reduction potential and on the redox potential of the half-cell reaction on the positive side of the device. If the n-type electroactive material enables high ion mobility, then the ion can reach the charge-collection layer more quickly and so the potential difference does not need to be particularly high to speed up the ions. The reduction potential may vary from the standard aqueous conditions as the ion may or may not be solvated to an equivalent extent by any coordinating groups from the n-type electroactive material.

The n-type electroactive material may be suitably selected depending on the purpose of the device and required ion mobility.

In a preferred embodiment, the n-type electroactive material comprises (or consists of) an n-type semiconductive polymer, which may be chemically modified so as to enhance its electrical conductivity and/or ion mobility. Preferably, the n-type semiconductive polymer exhibits an ion conductivity of at least 10⁻⁶Ω⁻¹·cm⁻¹ with respect to the metal(loid) ions used. The ionic conductivity referred to herein may be measured using traditional impedance analysis techniques for measuring ac-conductivity, for example, as described in British Library Cataloguing in Publication Data Electrochemistry (Chemical Society, Specialist periodical reports), The Chemical Society, Burlington House, London WIVOBN, Vol. 7 (1980); West, A. R., Solid State Chemistry and Its Applications, John Wiley & Sons Ltd., (1984); and R. D. Armstrong, T. Dickinson, P. M. Willis, Electroanalytical Chemistry and Interfacial Electrochemistry, Vol. 53, 389 (1974).

In one embodiment, the n-type electroactive material may be a blend of an n-type semiconductive polymer and an ion-conductive polymer.

As examples of the n-type semiconductive polymer, polyethers (including e.g. poly(ethylene oxide) (PEO) (also referred to as polyethylene glycol (PEG)) or polypropylene oxide (PPO)), polyether derivatives or co-polymers comprising a polyether or a polyether derivative may be mentioned.

The optional ion-conductive polymer is not particularly limited as long as it is chemically stable to the metal(loid) to be electrodeposited, and miscible and compatible with the n-type semiconductive polymer. It may be chosen appropriately depending on its ability to form ionized metal-salt complexes and maintain a sufficient ionic mobility of the metal(loid) ions used. Preferably, the ion-conductive polymer exhibits an ion conductivity of at least 10⁻⁵Ω⁻¹·cm⁻¹ with respect to the metal(loid) ions used. Suitable ion-conductive polymers may be homo- and co-polymers selected from polymers which do not contain chemical groups which may be reduced in the presence of the electrodeposited metal(loid), such as e.g. carboxyl, ketone, or hydroxyl groups. As examples, polyethers; poly(crown ethers); poly(styrenes); polybutadiene; polyisoprene; derivatives of these polymers; and blends thereof may be mentioned, wherein these polymers differ from the n-type semiconductive polymer used. In a preferred embodiment, the metal or metalloid constituting the metal or metalloid ions have a lower work function than the material constituting the negative charge collection layer. In a further preferred embodiment, the metal or metalloid constituting the metal or metalloid ions has a work function of less than 4.5 eV, more preferably less than 4.2 eV. As preferred examples, alkaline metals, alkaline earth metals and Zn may be mentioned. In general, it is also possible to deposit multiple metal(loid)s and a mixture of a metal or a metalloid, for example. Preferably, the metal(loid) ions are introduced into the plating composition as a metal(loid) salt, which is then where the metal(loid) cations comprised in the salt consist of the material that is to be deposited, and the associated anions are electrochemically inert or may be chosen so as to provide an additional function based on the specific requirements of each device. As examples for anions that are generally stable under operational conditions, I⁻, Br⁻, Cl⁻, ClO₄⁻, PF₆⁻, BF₄⁻, sulfonates, alkylborates, arylborates, and fluorinated organoborates may be mentioned.

Independently, or in combination therewith, it is preferred that the material constituting the negative charge collection layer has a work function of at least 4.2 eV, more preferably at least 4.5 eV. Preferred examples of such materials are Pt, Au, Cu, Ag, stainless steel or transparent conductive oxides, such as e.g. indium-tin oxide (ITO), indium-zinc oxide, aluminum-tin oxide, antimony-tin oxide, zinc oxide, indium oxide and tin oxide. The charge collection layer may further comprise a plurality of these materials.

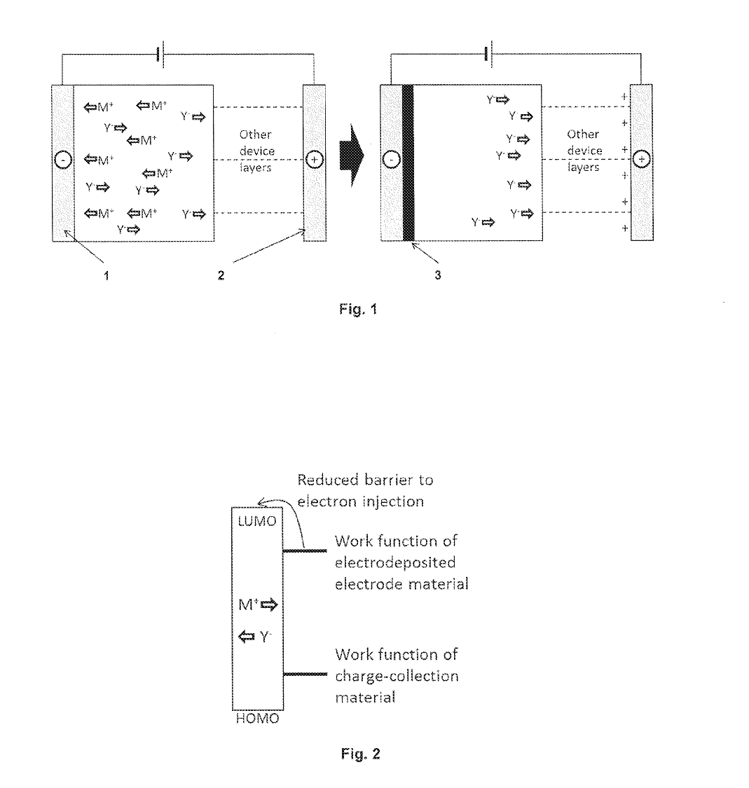

By using metal or metalloid ions having a lower work function than the material constituting the negative charge collection layer, it is ensured that the negatively-biased charge collection material does not inject directly into the LUMO of the polymer material at a voltage that is consistent with stable operation. However, it will allow to electrochemically reduce the metal ions to the metal at a lower potential as they are positively charged. Accordingly, the deposited low-work function metal aligns the Fermi levels with the charge-collection material and, once the electrode layer is thick enough, it is capable of injecting into the LUMO of the polymer with a greatly reduced energy barrier due to its lower work function (see FIG. 2).

The term “work function”, as used herein, denotes the energy difference between an electron at rest at infinity and an electron at the Fermi level in the interior of the substance. It thus reflects the minimum energy required to remove an electron from the interior of a solid to a point just outside the surface and represents a common literature value (reference value). Work functions of a number of exemplary metals and metalloids as compiled by H. B. Michaelson, Journal of Applied Physics 1977, vol. 48, no. 11, pp. 4729-4733, are given in Table 1 below.

TABLE 1

| material | work function (eV) |
|---|---|
| Cs | 2.14 |
| Rb | 2.16 |
| K | 2.3 |
| Sr | 2.59 |
| Ba | 2.7 |
| Na | 2.75 |
| Ca | 2.87 |
| Li | 2.9 |
| Y | 3.1 |
| Sc | 3.5 |
| La | 3.5 |
| Mg | 3.66 |
| As | 3.75 |
| Zr | 4.05 |
| Mn | 4.1 |
| Ag | 4.26 |
| Al | 4.28 |
| V | 4.3 |
| Nb | 4.3 |
| Ti | 4.33 |
| Zn | 4.33 |
| Cr | 4.5 |
| Fe | 4.5 |
| W | 4.55 |
| Sb | 4.55 |
| Mo | 4.6 |
| Cu | 4.65 |
| Ru | 4.71 |
| Os | 4.83 |
| Re | 4.96 |
| Be | 4.98 |
| Co | 5 |
| Ge | 5 |
| Au | 5.1 |
| Pd | 5.12 |
| Ni | 5.15 |
| Ir | 5.27 |
| Pt | 5.65 |

The contents of n-type electroactive material and metal(loid) ions used in the electrodeposition layer may be independently chosen in view of the desired thickness of the deposited electrode layer, taking further into account the mobility of the ions in the n-type electroactive material and the electrodeposition conditions used.

The thickness of the electrodeposition layer may be appropriately chosen in view of its composition (e.g. metal(loid) ion concentration), the electrodeposition conditions and the desired device configuration and function. Preferably, the target thickness of the electrodeposited electrode layer is within the range of from 1 nm to 1000 nm, more preferably within the range of from 1 nm to 500 nm.

The electrodeposition layer may comprise further additives, provided that they do not interfere with the electrodeposition process and the functioning of the manufactured device. For example, the layer may comprise a solvent, solvents being materials other than the liquid salt which are liquid under the conditions at which the method is carried out. In particular, the solvent may be chosen from organic solvents and inorganic solvents other than water.

The electrodeposition process may be controlled by galvanostatic control (current control), potentiostatic, or at cell voltage control. In general, parameters that can be controlled to adjust the properties of the formed electrode include cell voltage, cathode potential, and current conditions, such as e.g. the duration of the electrodeposition and total charge applied for the duration of the electrodeposition. Switching between multiple conditions and varying electrodeposition conditions may be applied in accordance with U.S. Pat. No. 8,227,293 B2 to alter the smoothness and/or homogeneity of the deposited electrode. In this regard, it is noted that the electrodeposition conditions may also be suitably selected so that the metal electrode is not deposited as a smooth film onto the charge-collection material, but instead forms dendrites that can propagate through the film, but are still in electrical contact with the charge-collection layer. This feature is often observed in layers of metal that are electrodeposited in devices such as batteries. While this can be a problematic step for these devices, dendritic deposition provides a very close electrical contact to the entire 3D structure of the polymer film and thus may represent an advantage in the present invention, provided that the quantity of metal is carefully chosen to be small enough that the dendrites do not grow to be too large and burst out of the polymer layer.

In a preferred embodiment of this invention, a metal salt is co-deposited in a film of an n-type semiconducting polymer, where the metal cations comprised in the salt consist of the material that is to be deposited, and the associated anions are electrochemically inert and do not impact the operation of the device. These anions may be chosen based on the specific requirements of each device.

It is a requirement of the electrochemical deposition of the metal electrode that an equivalent number of electrons are pulled out of the opposite (positively charged) charge-collection layer and that a charge-storage or oxidation process takes place at that interface. The anion from the metal salt may move through the device away from the anode towards the cathode and ionically counteract these injected charges, maintaining ion and charge neutrality throughout the system.

One may take advantage of this effect depending on the purpose of the finished device and the desired configuration. For example, by accumulating charge on positive electrode side onto a large (enough) surface area electrode, a function similar to that of an electrolytic capacitor or supercapacitor may be implemented. A further possibility would be to make use of an electrochemical oxidation of the anion to form a neutral species—this could include the production of an organic radical that could dimerise (e.g. an organic sulfide anion RS⁻, which is first oxidized to a radical RS. and then dimerises to RSSR), or the oxidation of a diol dianion to a quinone or related species. Another example is the oxidative doping of a charge injection layer, for example a polythiophene that is doped to form a highly conductive interface layer having ohmic contact with the positive electrode.

In a further aspect, the present invention relates to a method of enhancing charge injection in an electronic device or charge storage device comprising the steps of: pre-assembling an electronic device or charge storage device, wherein the pre-assembled device comprises a electrodeposition layer formed of a plating composition comprising metal or metalloid ions and an n-type electroactive material; optionally encapsulating the pre-assembled electronic device or charge storage device; and subsequently applying an electric field to effect electrodeposition of an electrode layer in situ by reducing the metal or metalloid ions to a non-ionic state.

It will be appreciated that the preferred features specified above may be combined in any combination, except for combinations where at least some of the features are mutually exclusive.

### Applications and Devices Comprising the In Situ Electrodeposited Electrodes

The methods of the present invention may be in principle applied to any device in which a moderately low work function metal is needed. Typically, it is difficult to apply a solution-deposited film in contact with any metal that would be oxidised by water (i.e. would have a negative electrode potential that would be unstable in the presence of solvents that had not been scrupulously dried). Thus, any application that requires a metal of this nature can take advantage of this invention.

Potential applications include but are not limited to electronic devices, such as light-emitting devices (including organic light-emitting diodes (OLED)), light-emitting chemical cells, photovoltaics, electronic circuits and components; and charge storage devices such as batteries.

In preferred embodiments of the present invention, the electronic device is a light-emitting diode or light-emitting electrochemical cell and the charge storage device is a thin film battery.

For the purpose of illustrating further advantages of the present invention, the application of in situ electrode formation will be exemplified on a number of selected devices and device configurations which may be manufactured by the aforementioned methods:

### Charge Storage Devices

Batteries or electrochemical cells represent devices converting chemical energy into electric energy using redox reactions and generally comprise a cathode, an anode, electrolyte and a separator to prevent short circuits between the electrodes.

These applications require that ions are available to move through the respective devices, and also that the material close to the positive electrode can be oxidised readily. Accordingly, when applying the methods of the present invention to manufacture these devices, it may be preferable to provide in the electrodeposition layer a higher content of the oxidisable polymer at the positive electrode side of the device, as this would enhance required electrochemistry to deposit the metal electrode on the other side of the device.

### Light-Emitting Diodes and Light-Emitting Electrochemical Cells

For applications of the methods of the present invention to light-emitting diodes or light-emitting electrochemical cells, it may be preferable that the concentration of mobile metal(loid) ions is controlled so as not to impart the proper functioning of the device.

The configuration of the multilayer structure used for the preparation of light-emitting diodes and light-emitting electrochemical cells may contain one (or more) additional layer(s), such as e.g. hole-injecting layers (HIL), electron-injecting layers (EIL), exciton-blocking layer (XBL), spacer layers, connecting layers and hole-blocking layers. One or more of these layers nay represent oxidisable materials to accommodate the ions and charges at the positive electrode side of the device.

While the performance might be somewhat limited by the reduced reflectivity of the electrodeposited anode (when compared to anodes provided by thermal evaporation or sputtering), this potential constraint may be outweighed by the simpler device preparation. For example, a negative charge-collection layer could be laminated into place from e.g. a flexible ITO (or equivalent) or even Al foil substrate, while the electrodeposition of the low work function anode would then enhance the electrical contact. Alternatively, an OLED device could benefit from the use of an oxidisable anion such as RS⁻ that can migrate through the device and be converted into the electrically neutral RSSR at the cathode side. An exemplary configuration for a light-emitting device is a bottom-emission OLED, which is comprised of one or more thin organic layers sandwiched between a high work function transparent anode (e.g. ITO) on a substrate and a cathode layer. When an electric field is applied across the two electrodes, holes and electrons are injected from the anode and the cathode, respectively. To reduce the effective injection barrier height at the organic/metal electrode interface and thereby achieve a satisfactory OLED performance, a low work function metal or metal alloy (e.g. Mg:Ag or Li:Al), which is conventionally deposited by vacuum thermal (co-)evaporation, is used as a cathode sublayer between the cathodic high work function material (e.g. Ag or Al) and the organic layer. As has been explained above, the reactivity of the low work function metal towards air and particularly trace quantities of solvents does not allow the high work function material to be deposited on top of the low work function material by a solution-based process without contaminating the electrode contact.

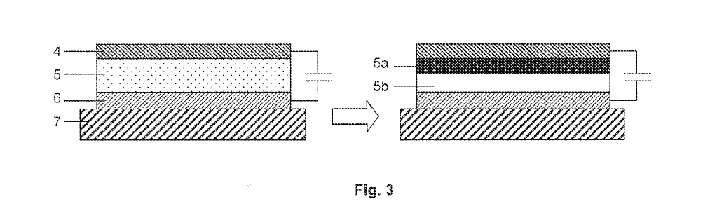

The method of manufacturing of a corresponding light-emitting device according to the present invention is schematically illustrated in FIG. 3. Initially, a device structure may be provided, wherein a high work function transparent anode layer (6) is positioned on top of a substrate layer (7) (e.g. glass substrate). An electrodeposition layer (5) comprising n-type electroactive material and metal or metalloid ions is provided on the anode layer (6). In this context, it is to be understood that the electrodeposition layer (5) does not need to be in direct contact with the anode layer, but that one or more layers (e.g. hole transporting layers) may be interposed between these layers. Thereafter, a negative charge collection layer (4) is provided on top and in contact with the electrodeposition layer (5) by any of the techniques specified above. Advantageously, the negative charge collection layer (4) may be a solution-processed layer, such as e.g. Ag ink. At this stage, the device structure may optionally be subjected to encapsulation by techniques known to the skilled artisan in order to prevent contamination with air and water. Before electrodeposition, the performance of the resulting configuration (see FIG. 3 left) is initially poor as the cathodic charge collection layer is not capable of effectively injecting electrons into the n-type material. However, by applying an electric field between the anode layer (6) and negative charge collection layer (4), as is shown on the right hand side of FIG. 3, the metal or metalloid ions comprised in the electrodeposition layer migrate towards the interface to negative charge collection layer (4) and are reduced to a non-ionic state, thereby forming an electrode layer (5a) in situ, while the n-type electroactive material (5b) retains the contact to the opposed interface. Thereby, electron injection into the n-type material is effectively enabled. Accordingly, since the fabrication of resulting OLED structure requires fewer steps and does not require elaborate equipment as it allows the use of solution-processed layers, the manufacturing method is simpler and less cost-intensive than conventional techniques.

Once given the above disclosure, many other features, modifications, and improvements will become apparent to the skilled artisan.

### REFERENCE SIGNS

1: negative charge-collection layer
2: positive charge-collection layer
3: electrode layer
4: negative charge-collection layer (cathode)
5: electrodeposition layer
5a: electrode layer
5b: n-type electroactive material
6: anode
7: substrate layer

1. A method of manufacturing an electronic device or a charge storage device, comprising the steps of:
providing a multilayer film comprising: a electrodeposition layer formed of a plating composition comprising metal or metalloid ions and an n-type electroactive material, and a negative charge-collection layer in contact with the electrodeposition layer; and
subsequently electrodepositing an electrode layer in situ on a surface of the negative charge collection layer by reducing the metal or metalloid ions to a non-ionic state.

2. The method of manufacturing an electronic device or a charge storage device according to claim 1, wherein the metal or metalloid ions are comprised in the plating composition as a metal(loid) salt.

3. The method of manufacturing an electronic device or a charge storage device according to claim 1, wherein the metal or metalloid ions are reduced to a non-ionic state irreversibly so as to form a permanent component of the device.

4. The method of manufacturing an electronic device or a charge storage device according to claim 1, wherein the multilayer film has been encapsulated against air and/or liquids prior to the electrodeposition step.

5. The method of manufacturing an electronic device or a charge storage device according to claim 1, wherein the electrodeposition layer is present in the multilayer film as an intermediate layer.

6. The method of manufacturing an electronic device or a charge storage device according to claim 1, wherein the n-type electroactive material comprises an n-type semiconductive polymer or a blend of an n-type semiconductive polymer with an ion-conductive polymer.

7. The method of manufacturing an electronic device or a charge storage device according to claim 1, wherein the n-type electroactive material exhibits an ion conductivity at least 10⁻⁶Ω⁻¹·cm⁻¹ with respect to the metal(loid) ions used.

8. The method of manufacturing an electronic device or a charge storage device according to claim 1, wherein the metal or metalloids have a lower work function in the non-ionic state than the material constituting the charge collection layer.

9. The method of manufacturing an electronic device or a charge storage device according to claim 1, wherein the metal or metalloids in the non-ionic state have a work function of less than 4.5 eV and the material constituting the charge collection layer has a work function of at least 4.5 eV.

10. The method of manufacturing an electronic device or a charge storage device according to claim 1, wherein the electrode layer is deposited as a dendritic structure.

11. The electronic device manufactured by the methods according to claim 1.

12. The electronic device according to claim 11, wherein the electronic device is a light-emitting diode or light-emitting electrochemical cell.

13. The charge storage device manufactured by the methods according to claim 1.

14. The charge storage device according to claim 13, wherein the charge storage device is a thin film battery.

15. A method of enhancing charge injection in an electronic device or charge storage device comprising the steps of:
pre-assembling an electronic device or charge storage device, wherein the pre-assembled device comprises a electrodeposition layer formed of a plating composition comprising metal or metalloid ions and an n-type electroactive material;
optionally encapsulating the pre-assembled electronic device or charge storage device; and
subsequently applying an electric field to the electronic device or charge storage device so as to effect electrodeposition of an electrode layer in situ by reducing the metal or metalloid ions to a non-ionic state.
